(19) United States
(12) Patent Application Publication
(10) Pub. No.: US 2009/0078570 A1
(43) Pub. Date: Mar. 26, 2009

(54) TARGET/BACKING PLATE CONSTRUCTIONS, AND METHODS OF FORMING TARGET/BACKING PLATE CONSTRUCTIONS

(76) Inventors: Wuwen Yi, Tempe, AZ (US); Ravi Rastogi, Liberty Lake, WA (US); Jaeyeon Kim, Liberty Lake, WA (US); Brett Clark, Spokane, WA (US); Susan D. Storhers, Mead, WA (US); Michael Pinter, Spokane, WA (US); Janine K. Kardokus, Varadale, WA (US)

Correspondence Address: HONEYWELL INTERNATIONAL INC., 101 COLUMBIA ROAD, P O BOX 2245, MORRISTOWN, NJ, 07962-2245, US

(21) Appl. No.: 12/259,998

(22) Filed: Oct. 28, 2008

Related U.S. Application Data
(63) Continuation-in-part of application No. 10/556,174, filed on Mar. 27, 2008.
(60) Provisional application No. 60/495,070, filed on Aug. 11, 2003.

(51) Int. Cl. C23C 14/34; B23K 1/20; B23K 28/00; B23K 20/08

(52) U.S. Cl. 204/298.13; 228/208; 228/194; 228/107

(57) ABSTRACT

Target/backing plate constructions and methods of forming target/backing plate constructions are disclosed herein. The targets and backing plates can be bonded to one another through an appropriate interlayer. The targets can comprise one or more of titanium, tantalum, titanium zirconium, hafnium, niobium, vanadium, tungsten, copper or a combination thereof. The interlayer can comprise one or more of silver, copper, nickel, tin, titanium and indium. Target/backing plate constructions of the present invention can have bond strengths of at least 20 ksi and an average grain size within the target of less than 80 microns.

This application is a continuation-in-part of U.S. application Ser. No. 10/556,174 filed on Nov. 8, 2005, which is a National Phase application based on PCT Application Serial No.: PCT/US504/25801 filed on Aug. 10, 2004.

### FIELD OF THE SUBJECT MATTER

The field of the subject matter is related to target/backing plate constructions, and also pertains to methods of forming target/backing plate constructions.

### BACKGROUND

Physical vapor deposition (PVD) is frequently utilized for deposition of materials. For instance, semiconductor processing frequently utilizes PVD for deposition of metals and/or other materials over semiconductor substrates.

A typical PVD operation utilizes a target comprising a desired material. The target is provided within a chamber of an appropriate apparatus. The target is typically bonded to a backing plate, and the backing plate is utilized to retain the target in a desired orientation within the apparatus. A substrate is provided in a location of the chamber spaced from the target. Desired material of the target is then sputtered or otherwise dislodged from the target, whereupon the, desired material deposits on the substrate.

Various difficulties can be encountered in bonding targets to backing plates. For instance, it the temperature utilized to bond the target to the backing plate is too high, grain sizes within the target can grow excessively. Generally, targets with smaller grain sizes are better for PVD processes than are targets containing larger grain sizes. Another problem which can occur in bonding targets to backing plates is that if the target/backing plate bond is not sufficiently strong, the bond can break under the repeated thermal stress associated with PVD processes. Particularly strong bonds can be desired for so-called ionized PVD (1-PVD) processes. The high powers typically utilized in I-PVD applications cause high gas temperatures (rarefication of the ionizing gas, thermalization of the sputtered metal species), which in turn can cause the temperature of the target to rise. It can be desired that target/backing plate assemblies have a bond strength between the target and backing plate of at least about 20,000 pounds per square inch (i.e., 20 ksi) in order to withstand the stresses associated with the high power levels of I-PVD processing.

Therefore, it would be desirable to develop target/backing plate assemblies having desired small grain sizes within the target, while also having desired high bond strengths.

### SUMMARY

Contemplated embodiments include a target/backing plate construction. The construction includes a target material, such as titanium, hafnium, tantalum, titanium zirconium, niobium, vanadium, tungsten, copper or a combination thereof. In some embodiments, a copper-containing target having an average grain size of less than 80 microns. The construction has a bond strength from the target to the backing plate of at least about 20 ksi.

In some embodiments, a contemplated construction includes a target comprising titanium, tantalum, titanium zirconium, hafnium, niobium, vanadium, tungsten, copper or a combination thereof, a backing plate, and an interlayer between the target and backing plate. The backing plate comprises at least about 0.1 weight percent (%) of each of copper, chromium, nickel and silicon with copper being the primary constituent in some contemplated embodiments. In particular aspects, the backing plate consists essentially of copper, chromium, nickel and silicon with the nickel being present to from about 2 weight percent (%) about 3 weight percent (%); the silicon being present to from about 0.4 weight percent (%) to about 0.8 weight percent (%); and the chromium being present to from about 0.1 weight percent (%) to about 0.8 weight percent (%). The interlayer can comprise one or more of silver, titanium, copper, nickel, tin and indium. In, particular aspects, the bond strength from the target to the backing plate through the interlayer at least about 20 ksi, while the average grain size within the target is less than 80 microns, and in some aspects less than or equal to about 45 microns.

In another embodiment, a target/backing plate construction is contemplated that contains a target predominately comprising (in other words, comprising more than 50%, (by weight) aluminum, a backing plates and an interlayer predominately comprising nickel or titanium between the target and the backing plate.

Methods of forming a contemplated target/backing plate construction are also disclosed. A target is provided. The target is of a first composition and has a first bonding surface. A backing plate is provided. The backing plate is of a second composition different from the first composition and has a second bonding surface. An interlayer composition is formed on one or both of the first and second bonding surfaces. The interlayer composition may comprise a material soluble in one or both of the first and second compositions. The target is bonded to the backing plate through the interlayer composition

### BRIEF DESCRIPTION OF THE FIGURES

FIG. 1 is a diagrammatic, cross-sectional view of a contemplated target/backing plate construction.

FIG. 2 is a top view of the FIG. 1 construction, with the cross-section of FIG. 1 extending along the line 1-1 of FIG. 2.

Table 1 shows stress data for a titanium-based target assembly.

Table 2 shows bond strength data for a tantalum-based target assembly.

### DETAILED DESCRIPTION

Sputtering targets contemplated herein may generally comprise any material that can be a) reliably formed into a sputtering target; b) sputtered from the target when bombarded by an energy source; and c) suitable for forming a final or precursor layer on a wafer or surface. Materials that are contemplated to make suitable sputtering targets are metals, metal alloys, conductive polymers, conductive composite materials, dielectric materials, hardmask materials and any other suitable sputtering material.

Contemplated embodiments include a target/backing plate construction. The construction includes a target material, such as titanium, hafnium, tantalum, titanium zirconium, niobium, vanadium, tungsten, copper or a combination thereof. In some embodiments, a copper-containing target having an average grain size of less than 80 microns. The construction has a bond strength from the target to the backing plate of at least about 20 ksi.

In some embodiments, a contemplated construction includes a target comprising titanium, tantalum, titanium zirconium, hafnium, niobium, vanadium, tungsten, copper or a combination thereof, a backing plate, and an interlayer between the target and backing plate. The backing plate comprises at least about 0.1 weight percent (%) of each of copper, chromium, nickel and silicon with copper being the primary constituent in some contemplated embodiments. In particular aspects, the backing plate consists essentially of copper, chromium, nickel and silicon with the nickel being present to from about 2 weight percent (%) about 3 weight percent (%); the silicon being present to from about 0.4 weight percent (%) to about 0.8 weight percent (%); and the chromium being present to from about 0.1 weight percent (%) to about 0.8 weight percent (%). The interlayer can comprise one or more of silver, titanium, copper, nickel, tin and indium. In, particular aspects, the bond strength from the target to the backing plate through the interlayer at least about 20 ksi, while the average grain size within the target is less than 80 microns, and in some aspects less than or equal to about 45 microns,

In another embodiment, a target/backing plate construction is contemplated that contains a target predominately comprising (in other words, comprising more than 50%, (by weight) aluminum, a backing plates and an interlayer predominately comprising nickel or titanium between the target and the backing plate.

Methods of forming a contemplated target/backing plate construction are also disclosed. A target is provided. The target is of a first composition and has a first bonding surface. A backing plate is provided. The backing plate is of a second composition different from the first composition and has a second bonding surface. An interlayer composition is formed on one or both of the first and second bonding surfaces. The interlayer composition may comprise a material soluble in one or both of the first and second compositions. The target is bonded to the backing plate through the interlayer composition.

As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Contemplated metals are those that can be provided in high-purity form and that generally comprise titanium, tantalum, hafnium, titanium zirconium, niobium, vanadium, tungsten, copper or a combination thereof. It should be understood that the phrase “and combinations thereof” is herein used to mean that there may be metal impurities in some of the sputtering targets, such as a copper sputtering target with chromium and aluminum impurities, or there may be an intentional combination of metals and other materials that make up the sputtering target, such as those targets comprising alloys, borides, carbides, fluorides, nitrides, silicides, oxides and others.

The term “metal” also includes alloys, metal/metal composites, metal ceramic composites, metal polymer composites, as well as other metal composites. Alloys contemplated herein comprise gold, antimony, arsenic, boron, copper, germanium, nickel, indium, palladium, phosphorus, silicon, cobalt, vanadium, iron, hafnium, titanium, iridium, zirconium, tungsten, silver, platinum, ruthenium, tantalum, tin, zinc, rhenium, and/or rhodium. Specific alloys include gold antimony, gold arsenic, gold boron, gold copper, gold germanium, gold nickel, gold nickel indium, gold palladium, gold phosphorus, gold silicon, gold silver platinum, gold tantalum, gold tin, gold zinc, palladium lithium, palladium manganese, palladium nickel, platinum palladium, palladium rhenium, platinum rhodium, silver arsenic, silver copper, silver gallium, silver gold, silver palladium, silver titanium, titanium zirconium, aluminum copper, aluminum silicon, aluminum silicon copper, aluminum titanium, chromium copper, chromium manganese palladium, chromium manganese platinum, chromium molybdenum, chromium ruthenium, cobalt platinum, cobalt zirconium niobium, cobalt zirconium rhodium, cobalt zirconium tantalum, copper nickel, iron aluminum, iron rhodium, iron tantalum, chromium silicon oxide, chromium vanadium, cobalt chromium, cobalt chromium nickel, cobalt chromium platinum, cobalt chromium tantalum, cobalt chromium tantalum platinum, cobalt iron, cobalt iron boron, cobalt iron chromium, cobalt iron zirconium, cobalt nickel, cobalt nickel chromium, cobalt nickel iron, cobalt nickel hafnium, cobalt niobium hafnium, cobalt niobium iron, cobalt niobium titanium, iron tantalum chromium, manganese iridium, manganese palladium platinum, manganese platinum, manganese rhodium, manganese ruthenium, nickel chromium, nickel chromium silicon, nickel cobalt iron, nickel iron, nickel iron chromium, nickel iron rhodium, nickel iron zirconium, nickel manganese, nickel vanadium, tungsten titanium, tantalum ruthenium, copper manganese, germanium antimony telluride, copper gallium, indium selenide, copper indium selenide and copper indium gallium selenide and/or combinations thereof.

As far as other materials that are contemplated herein for sputtering targets, the following combinations are considered examples of contemplated sputtering targets (although the list is not exhaustive): chromium boride, lanthanum boride, molybdenum boride, niobium boride, tantalum boride, titanium boride, tungsten boride, vanadium boride, zirconium boride, boron carbide, chromium carbide, molybdenum carbide, niobium carbide, silicon carbide, tantalum carbide, titanium carbide, tungsten carbide, vanadium carbide, zirconium carbide, aluminum fluoride, barium fluoride, calcium fluoride, cerium fluoride, cryolite, lithium fluoride, magnesium fluoride, potassium fluoride, rare earth fluorides, sodium fluoride, aluminum nitride, boron nitride, niobium nitride, silicon nitride, tantalum nitride, titanium nitride, vanadium nitride, zirconium nitride, chromium silicide, molybdenum silicide, niobium silicide, tantalum silicide, titanium silicide, tungsten silicide, vanadium silicide, zirconium silicide, aluminum oxide, antimony oxide, barium oxide, barium titanate, bismuth oxide, bismuth titanate, barium strontium titanate, chromium oxide, copper oxide, hafnium oxide, magnesium oxide, molybdenum oxide, niobium pentoxide, rare earth oxides, silicon dioxide, silicon monoxide, strontium oxide, strontium titanate, tantalum pentoxide, tin oxide, indium oxide, indium tin oxide, lanthanum aluminate, lanthanum oxide, lead titanate, lead zirconate, lead zirconate-titanate, titanium aluminide, lithium niobate, titanium oxide, tungsten oxide, yttrium oxide, zinc oxide, zirconium oxide, bismuth telluride, cadmium selenide, cadmium telluride, lead selenide, lead sulfide, lead telluride, molybdenum selenide, molybdenum sulfide, zinc selenide, zinc sulfide, zinc telluride and/or combinations thereof. In some embodiments, contemplated materials include those materials disclosed in U.S. Pat. No. 6,331,233, which is commonly-owned by Honeywell International Inc., and which is incorporated herein in its entirety by reference.

The backing material and/or the target surface material constituents may be provided by any suitable method, including a) buying the backing material and/or the surface material constituents from a supplier; b) preparing or producing the backing material and/or the surface material constituents in house using chemicals provided by another source and/or c) preparing or producing the backing material and/or the surface material constituents in house using chemicals also produced or provided in house or at the location.

The backing material and/or the surface material constituents may be combined by any suitable method known in the art or conventionally used, including melting the constituents and blending the molten constituents, processing the material constituents into shavings or pellets and combining the constituents by a mixing and pressure treating process, and the like.

A contemplated embodiment utilizes alloys or, other compositions comprising copper, chromium, nickel and silicon as backing plate materials (i.e., CuCrNiSi materials). A contemplated material can comprise from about 2 weight percent (%) to about 3 weight percent (%) nickel, from about 0.4 weight percent (%) to about 0.8 weight percent (%) silicon, from about 0.1 weight percent (%) to about 0.8 weight percent (%) chromium, and the balance copper (with the percentages listed as weight percent). Such material has a tensile strength of about 790 MPa, a yield strength of about 630 MPa, a hardness greater than 158 HB, an average coefficient of thermal expansion of about 17.3 μm/m.C, and an electrical conductivity at 20° C. of about 40% IACS. Such backing plate material can be referred to (and is referred to herein) as C18000. The backing plate material can be utilized in combination with high purity copper targets, such as, for example, targets having a copper purity of greater than 99.9% (i,e., 3N), by weight percent, and in particular applications copper targets having greater than 99.995% (i.e., 4N5) copper, such as, for example, targets having greater than or equal to 99.9999% (i.e., 6N) copper.

In the past, copper targets have typically been bonded to CuCr backing plates (with the backing plates typically comprising from about 0.6 weight percent to about 1.2 weight percent chromium, with the balance of the composition being copper). An advantage of CuCrNiSi backing plate constructions relative to the previously-utilized CuCr constructions can be that CuCrNiSi can have a more suitable conductivity for particular applications, and another advantage is that CuCrNiSi can have a more suitable strength for particular applications. Specifically, CuCrNiSi can have a higher strength and lower conductivity than CuCr.

Difficulties in utilizing CuCrNiSi occur in attempting to bond high-purity copper or titanium targets to the backing plates. Specifically, it is difficult to achieve a bond strength of 20 ksi or greater without utilizing conditions which grow a grain size within a copper or titanium target to an unacceptable size (with a typical unacceptable size being a grain size greater than or equal to 80 microns).

In some embodiments, an interlayer is utilized to couple the target material with the backing plate. In embodiments where titanium, tantalum or alloys thereof are utilized, an interlayer may or may not be used. In a contemplated embodiment, an interlayer is provided between a high-purity target comprising titanium, tantalum, hafnium, titanium zirconium, niobium, vanadium, tungsten, copper or a combination thereof and a CuCrNiSi backing plate. The interlayer can comprise, consist essentially of, or consist of, for example, one or more of silver, copper, titanium, nickel, tin, indium or combinations thereof. Such materials are preferred for the interlayer because there can be good diffusion between the materials and the backing plate and target.

A target is provided which comprises a first composition; and a backing plate is provided which comprises a second composition different from the first composition. The target has a bonding surface (which can be referred to as a first bonding surface) and the backing plate has a bonding surface (which can be referred to as a second bonding surface). The interlayer composition is provided on the bonding surface of the target and/or the bonding surface of the backing plate, and subsequently the target and backing plate are subjected to conditions causing bonding of the target and backing plate through the interlayer composition. The interlayer composition may be formed at least on the backing plate bonding surface in applications in which the backing plate comprises CuCrNiSi, in that the backing plate can have oxide surface which interferes with bonding unless the surface is disrupted prior to bonding. The provision of the interlayer composition on the surface can disrupt the oxide surface. The oxide may occur through oxidation of silicon associated with the CuCrNiSi. Regardless of the cause of the oxide, the oxide can be disrupted by a chemical treatment in addition to, or alternatively to, formation of the interlayer composition on the backing plate.

A contemplated chemical treatment is to treat a bonding surface of the backing plate with either hydrofluoric acid alone, or a combination of hydrofluoric acid and-nitric acid, to remove oxide from the surface. Such treatment can also remove silicon from the bonding surface, which can be desired in particular applications. An exemplary treatment process can comprise the following seven steps:
a bonding surface of the backing plate is exposed to a basic solution (with a suitable basic•solution being a sodium hydroxide solution formed from Metex T-103™);
the bonding surface is rinsed with deionized water;
the bonding surface is treated with a solution comprising nitric acid and hydrofluonic acid (such as, for example, a solution comprising about 43% nitric acid and about 4.9% hydrofluoric acid (v/v));
the bonding surface is rinsed with deionized water;
the bonding surface is treated with a solution comprising sulfuric acid (such as, for example, a solution comprising about 2.8% sulfuric acid (v/v));
the bonding surface is rinsed with deionized water; and
the backing plate is dried using high pressure air and then promptly vacuum bagged to avoid surface oxidation.

The treatment with the hydroxide (step 1) can occur for about 30 seconds, the treatment with the hydrofluoric acid/nitric acid mixture (step 3) can occur for about 10 seconds, and the treatment with the sulfuric acid (step 5) can occur for about 30 seconds, in typical applications.

The chemical treatment described above can be utilized with or without the interlayer composition described herein, but typically would be utilized as pretreatment in conjunction with applications that also utilized the interlayer composition. Similarly, the interlayer composition can be utilized with or without the chemical treatment described herein.

The interlayer, composition can be applied to the backing plate bonding surface and/or target bonding surface utilizing any suitable method, including, for example, ion plating, electroplating, electroless methodology, etc.

Once the interlayer composition has been applied to one or both of the target bonding surface and the backing plate bonding surface, the backing plate is bonded to the target utilizing, for example, hot isostatic pressing (HIP) at a temperature of from about 250° C. to about 1000° C., and the interlayer composition becomes an interlayer between the target and backing plate. In some embodiments, the hot isostatic pressing occurs at a temperature of from about 400° C. to about 900° C. In other embodiments the hot isostatic pressing occurs at a temperature of from about 500° C. to about 900° C. In yet other embodiments the hot isostatic pressing occurs at a temperature of from about 521° C. to about 889° C.

In applications in which the backing plate comprises, consists essentially of, or consists of CuCrNiSi; the interlayer comprises, consists essentially of, or consists of silver; and the target comprises high-purity copper, the bond strength between the target and backing plate can be at least about 20,000 lbs per square inch while an average grain size within the target remains less than 80 microns, and in some aspects while substantially all of the grains within the target have a maximum grain size of less than about 80 microns.

In one embodiment, copper is ion plated on bonding surfaces of both a 99.9999% Cu target and a CuCrNiSi backing plate prior to diffusion bonding. The ion plated layers are about 5 microns thick on the target and backing plate. The target and backing plate are diffusion bonded at 400° C. by HIP. The bond strength is about 20.4 ksi and the average target grain size is about 49 microns. When an identical target is bonded to an identical backing plate with HIP at 450° C. but without an interlayer, the bond strength is about 12.5 ksi and the average target grain size is about 210 microns.

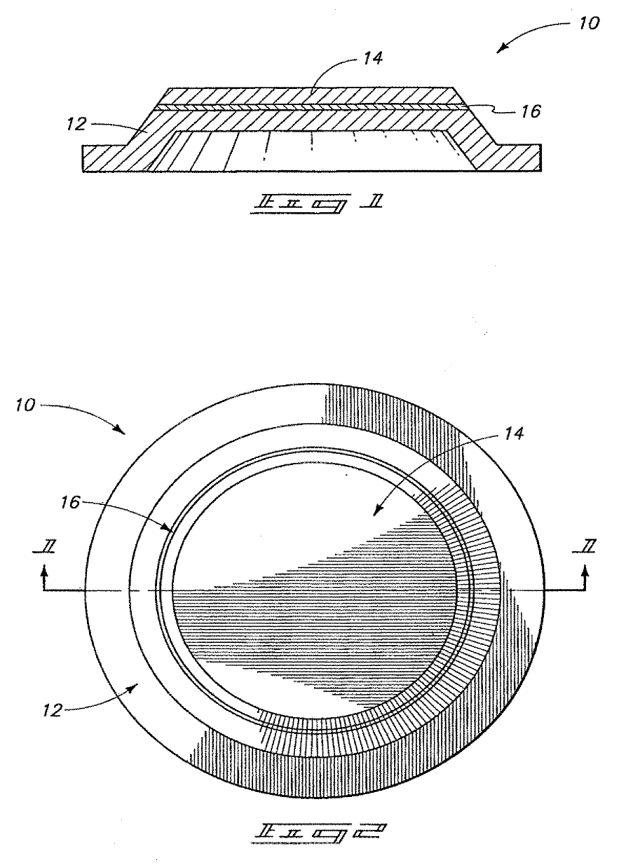

A contemplated target/backing plate construction 10 which can be formed in accordance with methodology disclosed herein is described with reference to FIGS. 1 and 2. The construction comprises a backing plate 12, a target 14, and an interlayer 16 between the target and backing plate (the interlayer is specifically at an interface between a bonding surface of the target and a bonding surface of the backing plate). The backing plate can, in particular aspects, comprise CuCrNiSi, the target can comprise high-purity titanium, tantalum, hafnium, titanium zirconium, niobium, vanadium, tungsten, copper or a combination thereof, and the interlayer can comprise one of silver, titanium, copper or a combination thereof. The interlayer will typically have a thickness of from about 0.1 microns to about 20 microns. Construction 10 is shown in an exemplary shape. It is to be understood that contemplated methods can be utilized to form numerous target/backing plate constructions, including, but not limited to, the shown shape of construction 10. Although the interlayer is shown as a single homogeneous composition, it is to be understood that the interlayer can, in some aspects, comprise a stack of differing compositions.

Methods disclosed herein can be particularly useful for bonding high-purity targets, comprising titanium, tantalum, hafnium, titanium zirconium, niobium, vanadium, tungsten, copper or a combination thereof to backing plates comprising CuCrNiSi in order to obtain high strength bonds while retaining small grain sizes in the high-purity copper material. However, it is to be understood that contemplated embodiments can be applied to other target/backing plate compositions. For instance, the target can comprise, consist essentially of, or consist of titanium, hafnium, tantalum, titanium zirconium, niobium, vanadium, tungsten, copper or a combination thereof, or can comprise any other composition-suitable for bonding through an appropriate interlayer. The backing plate can comprise one or more of copper, chromium, nickel and silicon, and in particular applications can be a backing plate of Cu and Cr.

The backing plate is not limited to the compositions described above, and can comprise any suitable composition which can be appropriately bonded to a suitable target utilizing the methodology described herein. In choosing an appropriate interlayer to utilize between a particular target and a particular backing plate, it can be desired to choose a material soluble in either of, and preferably both of, the target and backing plate compositions. If, for example, a target predominately comprising aluminum (by weight) is utilized, it can be desired to utilize an interlayer predominately comprising nickel or titanium (by weight). In some aspects, the target can consist essentially or consist of aluminum, and the interlayer can consist essentially of or consist of nickel or titanium.

Although HIP is described above for forming a bond between a target and backing plate, it is to be understood that contemplated methods can be utilized with other methods of bonding targets to backing plates. For instance, explosion bonding techniques can be utilized to bond Cu-containing targets to CurNiSi backing plates. An exemplary explosion bonding technique forms an approximate bond strength of at least about 45 ksi (and in particular aspects about 47 ksi) between a 99.9999% Cu target and a CuCrSiNi backing plate, and maintains a maximum target grain size of from about 38 microns to about 45 microns, with the average target grain size being less than or equal to about 45 microns (typically less than or equal to about 41 microns). The explosion bonding technique can be utilized without a chemical surface treatment of the backing plate, and without an interlayer between the backing plate and target.

In one embodiment, titanium is bonded to a CuCrNiSi backing plate in a non-plated assembly. In these assemblies, fine grain sizes are observed with these titanium targets, such as 9.2 and 9.8+Table 1 shows two sets of “maximum stress at maximum load (psi)” data collected for this embodiment. BP1 and BP2 indicate two separate runs of the same target assembly. The internal diameter of the target assembly is 0+752 inches. The outside diameter of the target assembly is 1.06 inches. The bond area is 0.44 inches. Typically, bond area is the area where the strength is being measured by using a ram tensile test or a similar procedure,

TABLE 1

| | Ti-C18000 BP 1 | Ti-C18000 BP 2 |
|---|---|---|
| | 51043.88 | 49789.05 |
| | 50732.01 | 50477.75 |
| | 50770.46 | 49706.4 |
| | 49606.14 | 50403.95 |
| | 49805.6 | 50509.73 |
| | 49760.93 | 50656.88 |
| | 50627.46 | 50539.71 |
| | 50592.01 | 50531.08 |
| | 49848.42 | 50324.29 |
| Av | 50310 | 50327 |
| STDEV | 514 | 322 |
| Max | 51044 | 50657 |
| Min | 49606 | 49706 |

Table 2 shows the bond strength a tantalum target assembly with and without copper plating/interlayer.

TABLE 2

| | Ta/C18000 | | | | |
|---|---|---|---|---|---|
| | (Cu plated/ | | ID | OD | |
| | interlayer) | Max stress | (internal | (outside | Bond |
| | Maximum | @ Max. | diameter - | diameter - | Area |
| Material: | Load lbf | load psi | inches) | inches) | in\hat{ } |
| 1 | 22483 | 51292 | 0.752 | 1.06 | 0.44 |
| 2 | 22482 | 51290 | 0.752 | 1.06 | 0.44 |
| 3 | 22037 | 50276 | 0.752 | 1.06 | 0.44 |
| Mean | 22334 | 50953 | | | |

| | Ta/C18000 | | | | |
|---|---|---|---|---|---|
| | not plated/no | | | | |
| | interlayer | Max stress | | | Bond |
| | Maximum | @ Max. | | OD | Area |
| Material: | Load lbf | load psi | ID | in | in\hat{ } |
| 1 | 16283 | 36950 | 0.75 | 1.06 | 0.44 |
| 2 | 15873 | 36019 | 0.75 | 1.06 | 0.44 |
| 3 | 17515 | 39746 | 0.75 | 1.06 | 0.44 |
| Mean | 16557 | 37572 | 0 | 1.06 | 0.44 |

Thus, specific embodiments and applications of target/backing plate constructions and their methods of production have been disclosed. It should be apparent, however, to those skilled in the art that many more modifications besides those already described are possible without departing from the inventive concepts herein. The inventive subject matter, therefore, is not to be restricted except in the spirit of the disclosure herein. Moreover, in interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. A target/backing plate construction, comprising:
a target comprising titanium, tantalum, titanium zirconium, niobium, vanadium, tungsten, hafnium, copper or a combination thereof;
a backing plate-comprising at least about 0.1 weight percent of each of copper, chromium, nickel and silicon;
an average grain size within the target of less than 80 microns; and
a bond strength between the target and backing plate of at least about 20 ksi.

2. The construction of claim 1 further comprising an interlayer between the target and backing plate, the interlayer comprising a different composition than both the target and the backing plate.

3. The construction of claim 2 wherein the interlayer comprises a thickness of from about 0.1 microns to about 20 microns:

4. The construction of claim 2 wherein the interlayer comprises one or more of silver, copper, titanium, nickel, tin and indium.

5. The construction of claim 1 wherein substantially all of the grains within the target are less than 60 microns.

6. The construction of claim 1 wherein the average grain size within the target is less than or equal to about 45 microns.

7. The construction of claim 1 wherein the backing plate consists essentially of the copper, chromium, nickel and silicon.

8. The construction of claim 1 wherein the backing plate consists essentially of the copper, chromium, nickel and silicon, and comprises:
from about 2 weight percent to about 3 weight percent of the nickel;
from about 0.4 weight percent to about 0.8 weight percent of the silicon; and
from about 0.1 weight percent to about 0.8 weight percent of the chromium.

9. A target/backing plate construction, comprising:
a target predominately comprising titanium, tantalum or alloys thereof;
a backing plate; and
an interlayer between the target and backing plate, the interlayer comprising one or more of silver, copper, titanium, nickel, tin, indium or a combination thereof.

10. A method of forming a target/backing plate construction, comprising:
providing target, the target being of a first composition and having a first bonding surface;
providing a backing plate, the backing plate being of a second composition different from the first composition and having a second bonding surface;
forming an interlayer composition on one or both of the first and second bonding surfaces, the interlayer composition predominately comprising a material soluble in one or both of the first and second compositions, and
bonding the target to the backing plate through the interlayer composition, the interlayer composition being between the bonded target and backing plate as an interlayer.

11. The method of claim 10 wherein the bonding comprises hot isostatic pressing.

12. The method of claim 10 wherein the bonding comprises explosion bonding.

13. The method of claim 10 wherein the interlayer composition is formed on only the first bonding surface prior to bonding the target to the backing plate.

14. The method of claim 10 wherein the interlayer composition is formed on only the second bonding surface prior to bonding the target to the backing.

15. The method of claim 10 wherein the interlayer composition is formed on both the first and second bonding surfaces prior to bonding the target to the backing plate.

16. The method of claim 10 wherein the target comprises titanium, tantalum, titanium zirconium, niobium, hafnium vanadium, tungsten, copper or a combination thereof having a purity of greater than 99.995%, the backing plate comprises CuCrNiSi, and the forming the interlayer composition comprises ion plating copper onto both the first and second bonding surfaces.

17. The method of claim 10 wherein the backing plate comprises CuCrNiSi and wherein the interlayer composition is formed on the second bonding surface prior to bonding the target to the backing plate.

18. The method of claim 17 wherein an oxide is over the second bonding surface prior to forming the interlayer composition on the second bonding surface, and further comprising subjecting the second bonding surface to chemical treatment to disrupt the oxide prior to forming the interlayer composition on the second bonding surface.

19. The method of claim 18 wherein the chemical treatment comprises subjecting the oxide to hydrofluoric acid.

20. The method of claim 18 wherein the chemical treatment comprises subjecting the oxide to a combination of hydrofluoric acid and nitric acid.
